(19) United States
(12) Patent Application Publication
(10) Pub. No.: US 2015/0332996 A1
(43) Pub. Date: Nov. 19, 2015

(54) INTERPOSER AND METHOD OF FABRICATING THE SAME

(71) Applicant: UNITED MICROELECTRONICS CORP., Hsin-Chu City (TW)

(72) Inventors: Chien-Li Kuo, Hsinchu City (TW); Kuei-Sheng Wu, Miaoli County (TW); Ming-Tse Lin, Hsinchu City (TW); Chung-Sung Chiang, Kaohsiung City (TW)

(73) Assignee: UNITED MICROELECTRONICS CORP., Hsin-Chu City (TW)

(21) Appl. No.: 14/280,680

(22) Filed: May 19, 2014

(51) Int. Cl. H01L 23/498; H01L 23/00; H01L 21/48; G03F 7/20

(52) U.S. Cl. CPC H01L 23/49838; G03F 7/70; H01L 24/17; H01L 24/81; H01L 21/4846; H01L 2224/1701; H01L 2224/16227

(57) ABSTRACT

The present invention provides an interposer including multiple circuit designs and an uppermost circuit design disposed on the circuit designs. A maximum exposure region is defined as a maximum size which can be defined by a single shot of a lithographic scanner. The sizes of the circuit designs below the uppermost circuit design are smaller than the size of the maximum exposure region. Therefore, the circuit designs are respectively formed by only a single shot of the lithographic scanner. The uppermost circuit design has a length greater than the length of the maximum exposure region, so that the circuit design is formed by stitching two photomasks lithographically.

### BACKGROUND OF THE INVENTION

1. Field of the Invention

The present disclosure relates to an interposer. More specifically, the present disclosure relates to an interposer with a large size, and a method of fabricating the same.

2. Description of the Prior Art

Modern multi-chip modules utilize interposers and through-silicon-via technologies to integrate multiple integrated circuit devices on a silicon substrate. An interposer is an electrical interface routing between sockets or connecting one socket to another socket. The purpose of an interposer is to widen the pitch of a connection from a bump pitch of a chip or to reroute a connection.

Compared to the organic, build-up substrate used in conventional flip-chip packages, a silicon interposer can provide much higher wiring densities due to silicon wafer fabrication processes employed in manufacturing silicon interposers.

As a result of the photomask size used in the lithographic processes for fabricating the interposers, however, the size of silicon interposers from leading foundries is currently limited to 26 mm×32 mm. This size limitation is a drawback for using a silicon interposer because the die sizes for high performance ICs are usually large.

### SUMMARY OF THE INVENTION

Therefore, it is desirable to design a larger interposer which can provide larger room for placing memory devices or other large size IC devices.

An embodiment relates generally to a method for fabricating an interposer. In such an embodiment, a first material layer is provided. Then, the first material layer is patterned to form a first circuit design by exposing a first photomask via a single shot of a lithographic scanner, wherein a maximum exposure region is a maximum field which can be defined by a single shot of the lithographic scanner, and a size of the first circuit design is smaller than a size of a maximum exposure region. Next, a second material layer is formed to cover the first material layer. Finally, the second material layer is patterned to form an uppermost circuit design by exposing at least a second photomask and a third photomask via at least two shots of the lithographic scanner. The uppermost circuit design is an uppermost conductive layer on the interposer, wherein the uppermost circuit design has at least one of the following properties: (a) a length greater than a length of the maximum exposure region, and (b) a width greater than a width of the maximum exposure region.

An embodiment relates generally to an interposer. In such an embodiment, an interposer includes a first circuit design, and an uppermost circuit design. A maximum exposure region is defined as a maximum size which can be defined via a single shot of a lithographic scanner, wherein a size of the first circuit design is smaller than a size of a maximum exposure region. The uppermost circuit design is disposed at an uppermost layer of the interposer, wherein the uppermost circuit design has at least one of the following properties: (a) a length greater than a length of the maximum exposure region, and (b) a width greater than a width of the maximum exposure region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a maximum exposure region defined by a single shot of a lithographic scanner onto a substrate.

FIG. 2 to FIG. 3 schematically show a first stage of a fabricating method of the present invention.

FIG. 4 to FIG. 8 schematically show a second stage of a fabricating method of the present invention.

FIG. 9 schematically shows a completed interposer.

FIG. 10 schematically depicts an uppermost circuit design with a large width.

FIG. 11 schematically depicts a method of dividing an image of an uppermost circuit design into four photomasks.

### DETAILED DESCRIPTION

The following description is a mode for carrying out the invention. This description is for the purpose of illustrating the general principles of the invention and should not be taken in a limiting sense. The scope of the invention is best determined by reference to the appended claims. Wherever possible, the same reference numbers are used in the drawings and the descriptions to refer to the same or like parts.

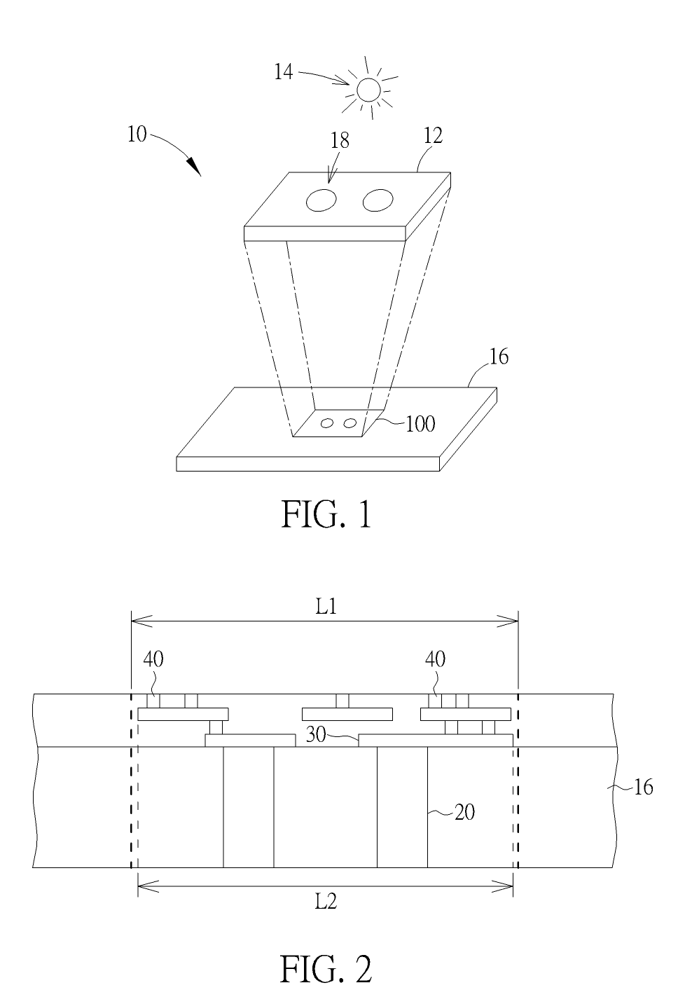

FIG. 1 to FIG. 11 schematically depict a fabricating method of a large interposer according to a preferred embodiment of the present invention, wherein like reference numerals are used to refer to like elements throughout. The implementation of the present invention is divided into two stages: firstly, several interconnection layers are formed on a substrate. The sizes of interconnection layers are all within the maximum exposure region (i.e. a maximum field which can be defined by a single shot of a lithographic scanner); and secondly, an uppermost circuit design is formed on the interconnection layers. The uppermost circuit design has at least one of the following properties: (a) a length greater than a length of the maximum exposure region, and (b) a width greater than a width of the maximum exposure region.

FIG. 1 shows a maximum exposure region defined by a single shot of a lithographic scanner onto a substrate. A lithographic scanner 10 includes a photomask 12, a light source 14 and lens (not shown). A substrate 16 is disposed below the photomask 12. The substrate 16 may be a semiconductor, a dielectric layer or a metal layer. The photomask 12 includes a pattern 18 thereon. The lithographic scanner 10 has a maximum exposure region 100, wherein the maximum exposure region 100 is a maximum field which can be defined by a single shot of the lithographic scanner 10 on a substrate 16. For example, a conventional scanner has a maximum exposure region of 26 mm by 33 mm.

FIG. 2 to FIG. 3 schematically show a first stage of a fabricating method of the present invention. Please refer to FIG. 1 and FIG. 2. During the first stage of the fabricating method, a circuit design 20 is created in a substrate 16 by using the lithographic scanner 10 to transfer the pattern 18 on the photomask 12 onto the substrate 16. The circuit design 20 is within the maximum exposure region 100 and may include several TSVs. A material layer such as a metal layer or a dielectric layer is used to cover the substrate 16 In this embodiment, the material layer exemplifies as a metal layer. Then, the material layer is patterned to form another circuit design 30 by using the lithographic scanner 10 with another photomask (not shown). Later, a dielectric layer may fills up the space between the circuit design 30. Similarly, the circuit design 30 is within the maximum exposure region 100. Next, subsequent circuit designs are stacked onto the previous circuit design by using the lithographic scanner 10. The first stage will be performed repeatedly until a circuit design 40 below the uppermost circuit design is formed. As shown in FIG. 2 and FIG. 3, a length L1 of the maximum exposure region 100 is marked by a dashed line, and a maximum length L2 among the circuit designs 20/30/40 is also shown. The length L2 is smaller than length L1. In other words, each circuit design 20/30/40 formed in the first stage has a length not greater than the length L1 of the maximum exposure region 100. Similarly, a width W1 of the maximum exposure region 100 is marked by a dashed line, and a maximum width W2 among the circuit designs 20/30/40 is also shown. The width W2 is smaller than width W1 . In other words, each circuit design 20/30/40 formed in the first stage has a width not greater than the width W1 of the maximum exposure region 100. As a result, a size of each circuit design 20/30/40 is smaller than a size of the maximum exposure region 100.

During the second stage of the fabricating method, an uppermost circuit design which has a length or a width exceeding that of the maximum exposure region is formed. Because the uppermost circuit design has a length greater than a length of the maximum exposure region and/or a width greater than a width of the maximum exposure region, the uppermost circuit design must be divided into image slices, which are thereafter lithographically stitched together during the lithographic process.

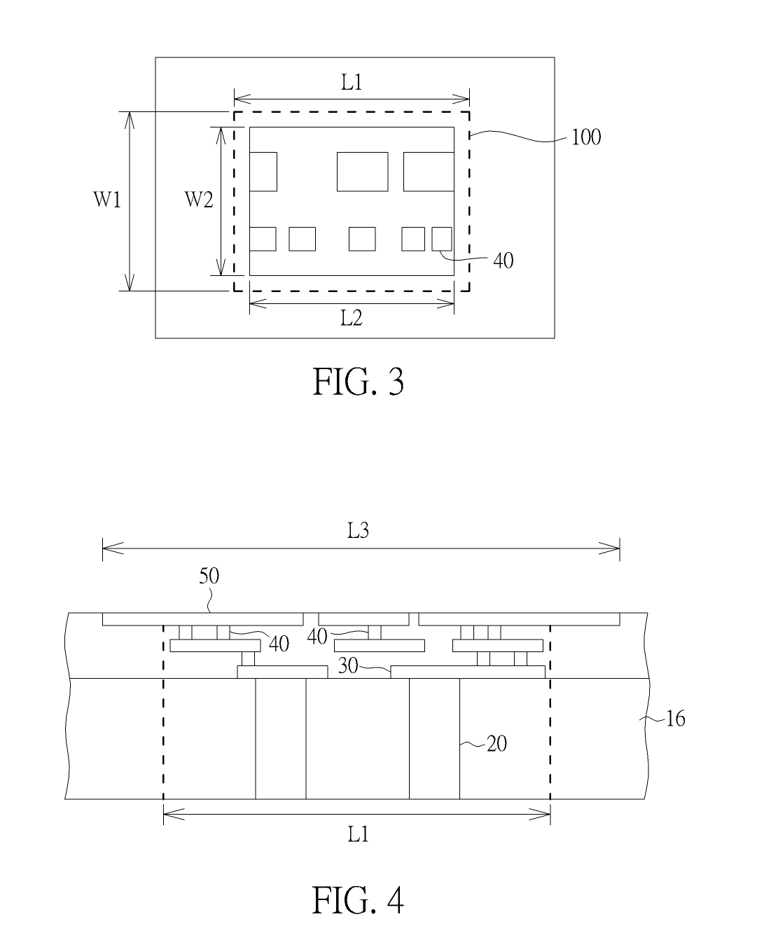

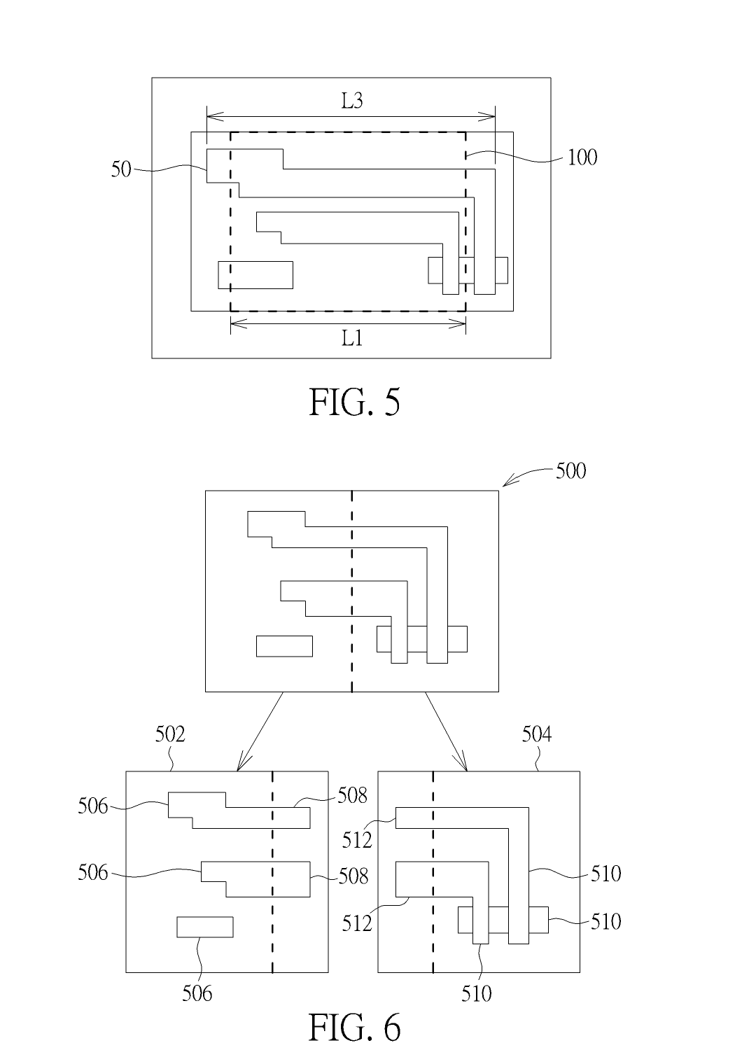

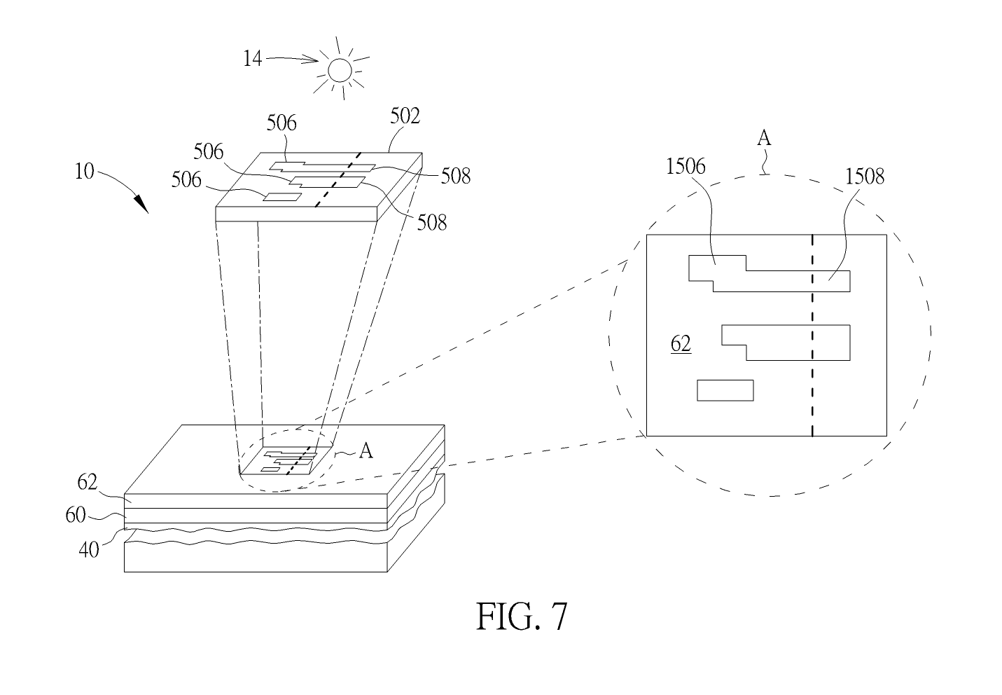

FIG. 4 to FIG. 8 schematically show a second stage of a fabricating method of the present invention. In FIG. 4 and FIG. 5, the uppermost circuit design 50 has a length L3 greater than the length L1 of the maximum exposure region 100. The length L1 of the maximum exposure region 100 is marked by a dashed line. The formation of the uppermost circuit design 50 in FIG. 4 and FIG. 5 will be detailed in the following description according to a preferred embodiment of the present invention. The formation of the uppermost circuit design 50 can be performed by a two-photo-one-etching process (2P1E) or a two-photo-two-etching process (2P2E) . The subsequent method illustrated in FIG. 6 to FIG. 8 will take the two-photo-one-etching process as an example.

As shown in FIG. 6, an image 500 of the uppermost circuit design 50 is divided into two image slices, which are then respectively output on two photomasks 502/504. The two image slices are separate by a dashed line shown on image 500. The image 500 corresponds to a layout of the uppermost circuit design 50. The photomask 502 includes a first pattern 506 and a first stitching mark 508. The first pattern 506 and the first stitching mark 508 are separated by a dashed line. The first pattern 506 is corresponding to the left part of image 500. The photomask 504 includes a second pattern 510, and the photomask 504 may further include a second stitching mark 512. The second pattern 510 and the second stitching mark 512 are separated by a dashed line. The second pattern 510 is corresponding to the right part of image 500. The first stitching mark 508 and the second stitching mark 512 are for assuring the first pattern 508 to stitch with the second pattern 510 perfectly. The first stitching mark 508 is substantially identical to part of the second pattern 510, and the second stitching mark 512 is substantially identical to part of the first pattern 506. The combination of the first pattern 506 and the second pattern 510 can form an image 500 of the uppermost circuit design through a lithographic process.

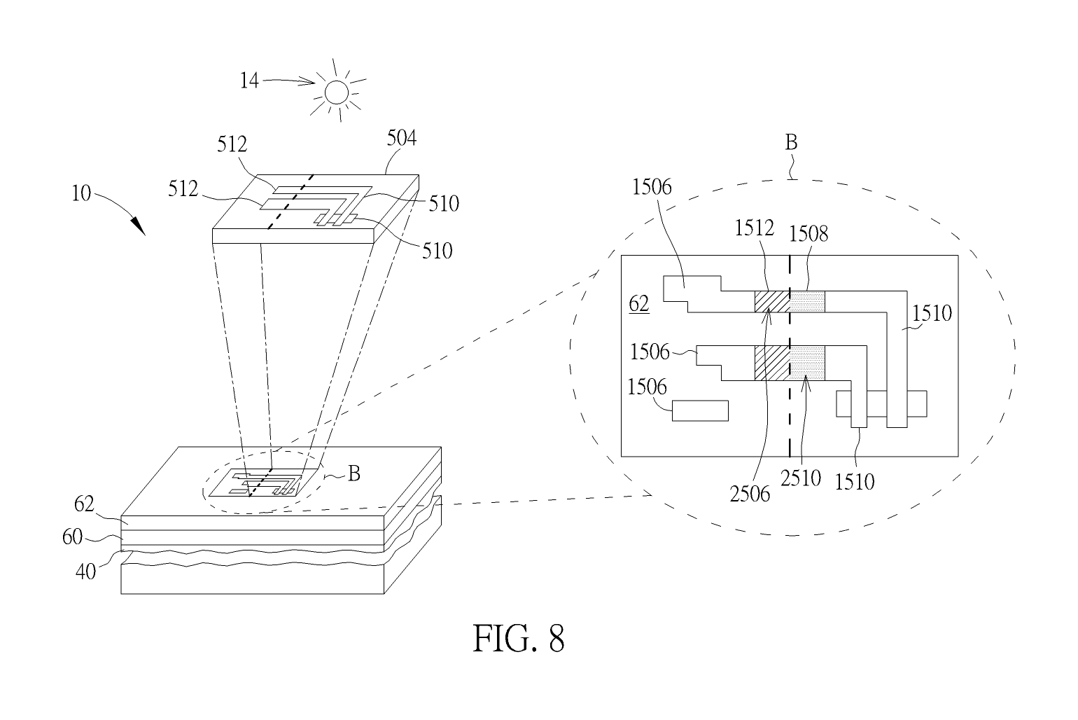

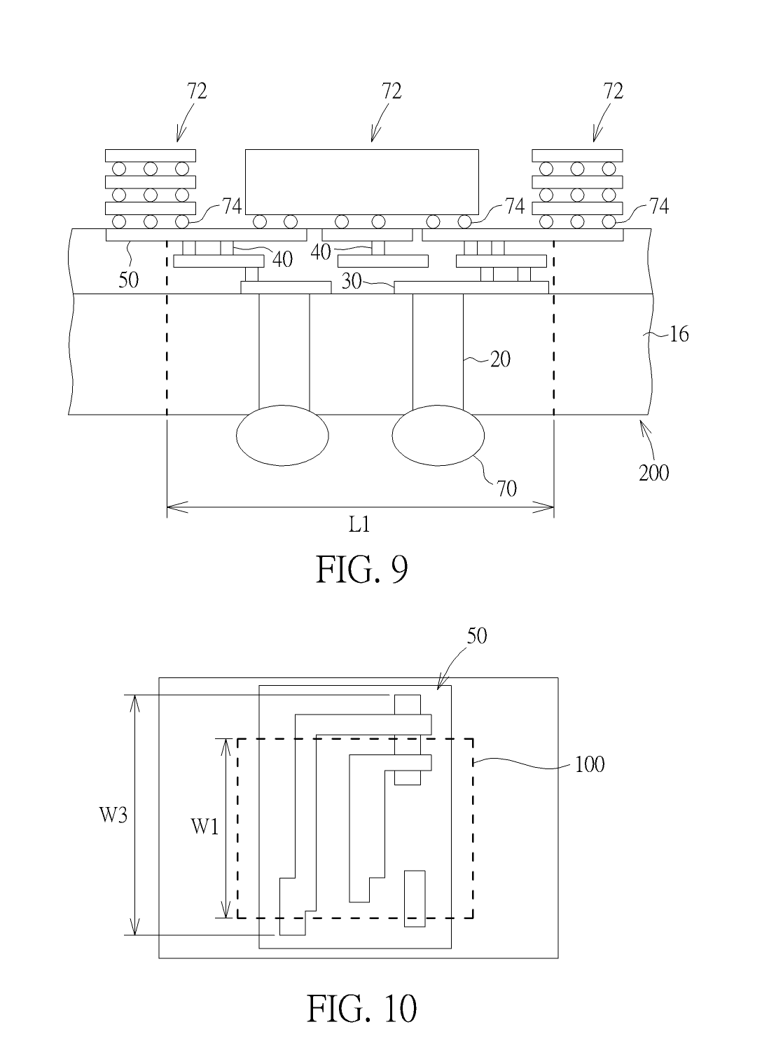

As shown in FIG. 7, the photomask 502 is loaded on the lithographic scanner 10. A material layer 60 is stacked on the circuit design 40. The material layer 60 may be a metal layer or a dielectric layer. In this embodiment, the material layer 60 is a metal layer such as aluminum. A photoresist layer 62 covers the material layer 60. Later, the first pattern 506 and the first stitching mark 508 are printed onto the photoresist layer 62 by the lithographic scanner 10 with the photomask 502. By using the lithographic scanner 10, the first pattern 506 on the photomask 502 forms a first circuit portion 1506 onto the photoresist layer 62, and the first stitching mark 508 on the photomask 502 forms a first stitching pattern 1508 onto the photoresist layer 62. The first circuit portion 1506 and the first stitching pattern 1508 are separate by a dashed line. For the sake of clarity, a magnified top view of the first circuit portion 1056 and the first stitching pattern 1508 on the photoresist layer 62 are shown in circle A. Next, as shown in FIG. 8, the photomask 504 is loaded on the lithographic scanner 10. The second pattern 510 and the second stitching mark 512 are printed onto the photoresist layer 62. The second pattern 510 forms a second circuit portion 1510, and the second stitching mark 512 forms a second stitching pattern 1512 onto the photoresist layer 62. The second circuit portion 1510 and second stitching pattern 1512 are separate by a dashed line. The second stitching pattern 1512 entirely overlaps a region 2506 of the first circuit portion 1506, therefore, the second stitching pattern 1512 becomes apart of the first circuit portion 1506. The first stitching pattern 1508 entirely overlaps a region 2510 of the second circuit portion 1510, therefore first stitching pattern 1508 becomes a part of the second circuit portion 1510. As a result, the first circuit portion 1506 and the second circuit portion 1510 form the upper circuit design 50. For the sake of clarity, a magnified top view of the first circuit portion 1056, the first stitching pattern 1508, the second circuit portion 1510 and the second stitching pattern 1512 on the photoresist layer 62 are shown in circle B. The region 2506 is marked by slashes, and the region 2510 is marked by dots. Referring back to FIG. 5, the material layer 60 is patterned by taking the photoresist layer 62 as a mask in order to form the uppermost circuit design 50. Then, the photoresist layer 62 is removed. Later, a dielectric layer fills up the space between the uppermost circuit design 50. The uppermost circuit design 50 has a length L3 greater than a length L1 of the maximum exposure region. At this point, the interposer 200 is completed. The uppermost circuit design 50 is an uppermost conductive layer on the interposer. As shown in FIG. 9, several bumps 70 are formed to electrically connect the circuit designs 20/30/40/50. Later, several chips 72 may be mounted on to the interposer 200. The uppermost circuit design 50 may contact microbumps 74 on each chip 72.

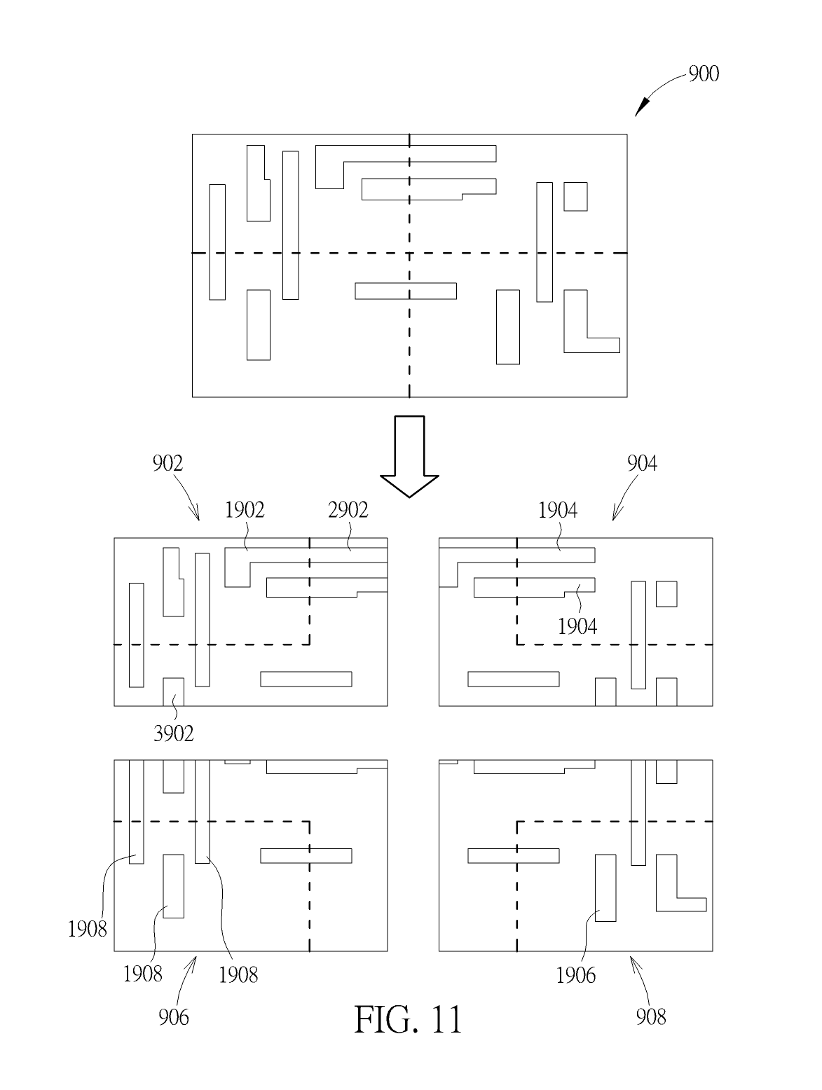

FIG. 10 schematically depicts an uppermost circuit design with a large width, wherein like reference numerals are used to refer to like elements throughout. As shown in FIG. 10, the uppermost circuit design 50 has a width W3 greater than a width W1 of the maximum exposure region 100. The uppermost circuit design 50 can be formed by dividing the image of the uppermost circuit design into two image slices. Then, multiple steps of a lithographic process can be performed by using a similar method to that illustrated in FIG. 6 to FIG. 8.

FIG. 11 schematically depicts a method of dividing an image of an uppermost circuit design into four photomasks. As shown in FIG. 11, if the uppermost circuit design has a length greater than a length of the maximum exposure region and a width greater than a width of the maximum exposure region, the uppermost circuit design can be formed by dividing the image 900 of the uppermost circuit design into four image slices. The four image slices can be respectively output to form four photomasks 902/904/906/908. Each photomask 902/904/906/908 includes a first pattern 1902, a second pattern 1904, a third pattern 1906 and a fourth pattern 1908. The combination of the first pattern 1902, the second pattern 1904, the third pattern 1906 and the fourth pattern 1908 may form the uppermost circuit design through lithographically stitching the four patterns.

Each photomask 902/904/906/908 further includes stitching marks respectively disposed adjacent to the four patterns 1902/1904/1906/1908. The stitching marks are separate from the pattern by dashed lines. The stitching mark may be substantially identical to part of the pattern which is not at the same photomask as the stitching mark, and each photomask 902/904/906/908 has at least two stitching marks. For example, the photomask 902 includes a first stitching mark 2902 and a second stitching mark 3902 disposed adjacent to the first pattern 1902. The first pattern 1902, the first stitching mark 2902 and the second stitching mark 3902 are separated by a dashed line. The first stitching mark 2902 is substantially identical to part of the second pattern 1904; the second stitching mark 3902 is substantially identical to part of the third pattern 1908. Then, multiple steps of the lithographic process can be performed by stitching the four photommasks 902/904/906/908.

As shown in FIG. 2 to FIG. 5 of the present invention, the sizes of the circuit designs 20/30/40 below the uppermost circuit design 50 are smaller than the size of the maximum exposure region 100. Therefore, the circuit designs 20/30/40 are respectively formed via only a single shot of the lithographic scanner. The uppermost circuit design 50 has a length L3 greater than the length L1 of the maximum exposure region. Therefore, the circuit design 50 is formed by lithographically stitching two photomasks. By using the method of the present invention, multiple lithographical processes are only required for the uppermost circuit design. Therefore, the manufacturing cost can be reduced, and a larger interposer can be achieved.

Those skilled in the art will readily observe that numerous modifications and alterations of the device and method may be made while retaining the teachings of the invention. Accordingly, the above disclosure should be construed as limited only by the metes and bounds of the appended claims.

1. A fabricating method of an interposer comprising:
providing a first material layer;
patterning the first material layer to form a first circuit design by exposing a first photomask by a single shot of a lithographic scanner, wherein a maximum exposure region is a maximum field which can be defined by a single shot of the lithographic scanner, and a size of the first circuit design is smaller than a size of a maximum exposure region;
forming a second material layer covering the first material layer; and
patterning the second material layer to form a uppermost circuit design by exposing at least a second photomask and a third photomask by at least two shots of the lithographic scanner, wherein the uppermost circuit design is an uppermost conductive layer on the interposer, and the uppermost circuit design has at least one of: (a) a length greater than a length of the maximum exposure region, and (b) a width greater than a width of the maximum exposure region.

2. The fabricating method of an interposer of claim 1, wherein the second photomask and the third photomask form an image of the uppermost circuit design through the lithographic scanner.

3. The fabricating method of an interposer of claim 1, wherein the second photomask comprises a first pattern and a first stitching mark, and the third photomask comprises a second pattern and a second stitching mark.

4. The fabricating method of an interposer of claim 3, wherein the first stitching mark is substantially identical to part of the second pattern, and the second stitching mark is substantially identical to part of the first pattern.

5. The fabricating method of an interposer of claim 4, wherein the steps of patterning the second material layer comprises forming a photoresist layer covering the second material layer;
projecting the first pattern and first stitching mark onto the photoresist layer to form a first circuit portion and a first stitching pattern;
projecting the second pattern and the second stitching mark onto the photoresist layer to form a second circuit portion and a second stitching pattern, wherein the second stitching pattern entirely overlaps a region of the first circuit portion; and
patterning the second material layer by taking the photoresist layer as a mask to form the upper circuit design.

6. The fabricating method of an interposer of claim 5, wherein the first stitching pattern entirely overlaps a region of the second circuit portion.

7. The fabricating method of an interposer of claim 5, wherein the first circuit portion and the second circuit portion form the uppermost circuit design.

8. The fabricating method of an interposer of claim 5, wherein the steps of patterning the second material layer further comprise projecting a third pattern on a fourth photomask onto the photoresist layer.

9. The fabricating method of an interposer of claim 8, wherein the second photomask further comprises a fourth stitching mark which is substantially identical to part of the third pattern.

10. The fabricating method of an interposer of claim 1, wherein the first material layer comprises a semiconductor, a dielectric layer or a metal layer.

11. The fabricating method of an interposer of claim 1, further comprising mounting a chip having microbumps on the interposer, wherein the microbumps contact the uppermost circuit design.

12. The fabricating method of an interposer of claim 1, further comprising before forming an uppermost circuit design, forming multiple circuit designs arranged tier upon tier and disposed on the first circuit design, wherein each of the circuit designs has a size smaller than the size of a maximum exposure region.

13. An interposer, comprising
a first circuit design, wherein a maximum exposure region is defined as a maximum size which can be defined by a single shot of a lithographic scanner, and a size of the first circuit design is smaller than a size of a maximum exposure region; and
an uppermost circuit design disposed at an uppermost layer of the interposer, wherein the uppermost circuit design has at least one of: (a) a length greater than a length of the maximum exposure region, and (b) a width greater than a width of the maximum exposure region.

14. The interposer of claim 13, further comprising multiple circuit designs arranged tier upon tier and disposed below the uppermost circuit design, wherein each of the circuit designs has a size smaller than the size of a maximum exposure region.

15. The interposer of claim 13, further comprising a chip having microbumps disposed on the interposer, wherein the microbumps contact the uppermost circuit design.
